(19) United States
(12) Patent Application Publication
(10) Pub. No.: US 2008/0093596 A1
(43) Pub. Date: Apr. 24, 2008

(54) Semiconductor Device and Method of Fabricating the Same

(76) Inventors: Ji-young Shin, Seoul (KR); Hyung-moo Park, Seoul (KR)

Correspondence Address: F. CHAU & ASSOCIATES, LLC, 130 WOODBURY ROAD, WOODBURY, NY, 11797, US

(21) Appl. No.: 11/858,655

(22) Filed: Sep. 20, 2007

(30) Foreign Application Priority Data
Oct. 23, 2006 (KR) 10-2006-0103017

(51) Int. Cl. H01L 23/48; H01L 21/44

(52) U.S. Cl. 257/48; 438/612; 257/E23.01; 257/E21.476

(57) ABSTRACT

A semiconductor device includes a wiring layer that is formed on a substrate and includes a first pad contact region and a second pad contact region, a passivation layer that includes a first opening and a second opening on the wiring layer and a protrusion pattern dividing the first opening and the second opening, and a pad metal pattern that is conformally formed along the first opening, the second opening, and the protrusion pattern of the passivation layer. The first pad contact region is exposed through the first opening and the second pad contact region is exposed through the second opening.

### CROSS REFERENCE TO RELATED APPLICATION

This application claims priority from Korean Patent Application No. 10-2006-0103017 filed on Oct. 23, 2006 in the Korean Intellectual Property Office, the disclosure of which is herein incorporated by reference in its entirety.

### BACKGROUND OF THE INVENTION

1. Field of the Invention

The present disclosure is directed to a semiconductor device and a method of fabricating the semiconductor device, and more particularly, to a semiconductor device in which a pad is divided into a probing area and a bonding area to prevent a bonding pad from being damaged by a probe tip and a method of fabricating the semiconductor device.

2. Description of the Related Art

When manufacturing of a semiconductor chip is completed, a semiconductor chip undergoes an EDS (Electrical Die Sorting) test process for evaluating electrical characteristics of a product before packaging. The EDS test is performed in such a manner that a probe tip attached to a probe card is brought in contact with a plurality of pads provided on a semiconductor chip to determine whether integrated circuits inside the chip operate normally or not. Therefore, as a semiconductor chip undergos the EDS test, the surface of the bonding pad may be scratched by the probe tip, thus being damaged.

In particular, recently, chips have not only a simple logic function but also a DRAM or SRAM embedded therein. For this reason, a bonding pad is exposed several times to possible probing damage. For example, in the case of a logic chip having an SRAM embedded therein, the logic chip includes logic and the SRAM. Accordingly, tests are performed before/after laser repair, that is, an SRAM pre-test is performed once before the laser repair, and an SRAM post-test is performed once after the laser repair. Further, the EDS test is performed on the logic. In this case, since the EDS test is executed at least three times, the surface of the bonding pad may be scratched by the probe tip several times, thus being damaged. In addition, if the probe tip is pushed, the pressure of the probe tip makes a probe mark deeper and larger.

Damages to the surface of the pad due to frequent contact with the probe tip and the pressure of the probe tip may cause defects during a semiconductor package bonding process. The bonding process is a process of bonding wires or ball type conductive materials to electrically connect an external power source and signals of a semiconductor device. While performing the bonding process, bonding contact may be unstable and defects may occur, because of the damaged surface of the pad.

### SUMMARY OF THE INVENTION

According to an aspect of the present invention, there is provided a semiconductor device including: a wiring layer formed on a substrate and including a first pad contact region and a second pad contact region; a passivation layer including a first opening through which the first pad contact region is exposed and a second opening through which the second pad contact region is exposed on the wiring layer and a protrusion pattern dividing the first opening and the second opening; and a pad metal pattern conformally formed along the first opening, the second opening, and the protrusion pattern of the passivation layer.

According to another aspect of the present invention, there is provided a method of fabricating a semiconductor device, the method including: forming a wiring layer including a first pad contact region and a second pad contact region on a substrate; forming a passivation layer on the wiring layer; forming a protrusion pattern dividing a first opening through which the first pad contact region is exposed and a second opening through which the second pad contact region is exposed by etching the passivation layer; and forming a pad metal pattern by patterning a pad metal layer along the first opening, the second opening, and the protrusion pattern of the passivation layer.

Other aspects of the present invention will be included in the detailed description of the invention and the drawings.

### BRIEF DESCRIPTION OF THE DRAWINGS

The above and other features of embodiments of the present invention will become more apparent by describing in detail preferred embodiments thereof with reference to the attached drawings.

FIG. 1 is a plan view illustrating a semiconductor device according to an embodiment of the invention.

FIG. 2A is a plan view of a pad of FIG. 1.

FIG. 2B is a cross-sectional view of the pad taken along the line B-B′ of FIG. 2A.

FIGS. 3 to 5 are cross-sectional views subsequently illustrating processes of fabricating the pad of FIG. 2B.

FIG. 6 is a cross-sectional view illustrating a pad according to another embodiment of the invention.

### DETAILED DESCRIPTION OF THE EXEMPLARY EMBODIMENTS

Features of embodiments of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. The same reference numerals are used to designate the same elements throughout the specification and drawings. Also, the terminology used herein is for the purpose of describing particular embodiments only and is not intended to be limiting of the invention.

Hereinafter, a semiconductor device in which a probing area and a bonding area are divided will be described with reference to the accompanying drawings.

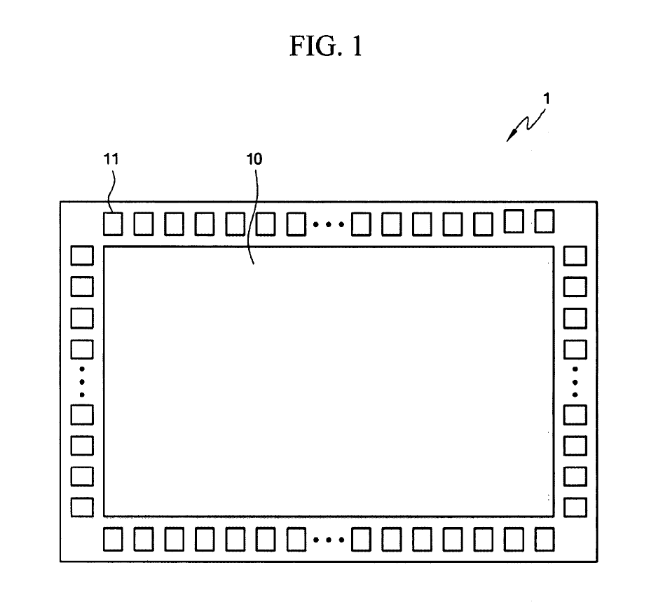

FIG. 1 is a plan view illustrating a semiconductor device according to an embodiment of the invention.

A semiconductor device 1 includes a core circuit part 10 and a plurality of pads 11.

The core circuit part 10 is located at the center of the semiconductor device 1 and includes actual circuits constituting an integrated circuit to be electrically operated.

The plurality of pads 11 is formed along the edge of the semiconductor device 1. Each of the pads 11 is electrically connected to the core circuit part 10 at the center so as to become a probing area which can be connected to a probe tip for connection with a test device after completing the fabricating of a semiconductor substrate, and to become a bonding area after completing the test.

In the pad 11, which is divided into a probing area and a bonding area according to this embodiment of the present invention, even though the probe tip is pushed in a wafer test process, the probe tip is prevented from intruding into the bonding area, thereby preventing bonding defects due to damage of a contact surface while performing a bonding process.

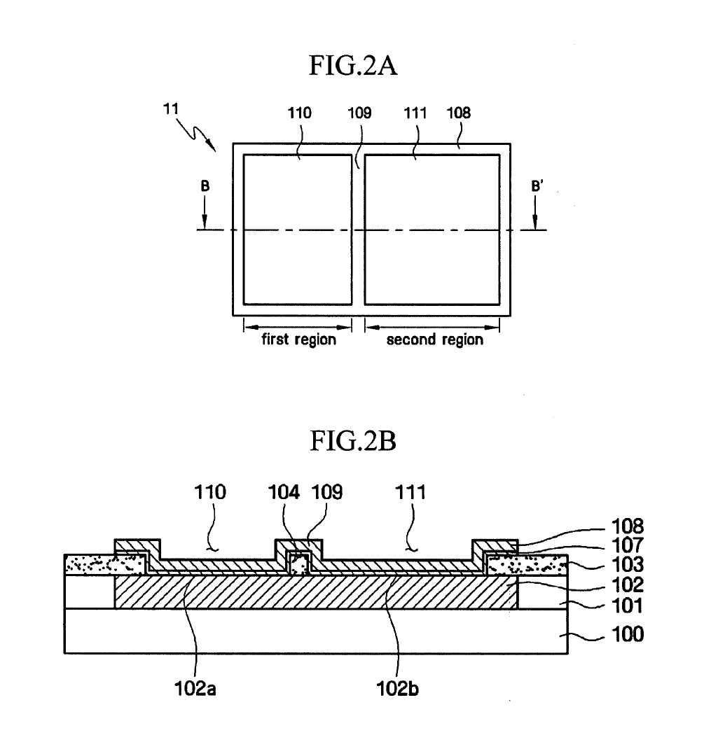

Description will be given with reference to FIGS. 2A and 2B. FIG. 2A is a plan view of the pad 11 of FIG. 1. FIG. 2B is a cross-sectional view of the pad taken along the line B-B′ of FIG. 2A.

First, although not shown, a semiconductor substrate 100 includes a lower structure such as a plurality of transistors and capacitors. Here, the semiconductor substrate 100 may be a silicon substrate or an SOI (Silicon On Insulator) substrate.

An interlayer insulating film 101 is located on the semiconductor substrate 100, and a wiring layer 102 is located on the interlayer insulating film 101 to be electrically connected to each transistor.

The interlayer insulating film 101 may be, for example, a silicon oxide film (SiOx), a silicon oxynitride film (SiON), a titanium oxide film (TiOx), a tantalium oxide film (TaOx), or the like. Here, the interlayer insulating film 101 is exemplified as a single layer, but the interlayer insulating film may have multiple layers in which a plurality of interlayer insulating films are laminated. In addition, a plurality of wiring layers may be interposed between the plurality of interlayer insulating films.

The wiring layer 102 located on the interlayer insulating film 101 includes a first pad contact region 102a and a second pad contact region 102b.

In this case, the wiring layer 102 is an uppermost wiring layer, which is formed of aluminum, copper, tungsten, etc. For convenience sake, according to thist embodiment of the invention, the wiring layer is exemplified as a copper wiring line that is formed by a damascene process, but it is not limited thereto. The first and second pad contact regions 102a and 102b of the wiring layer 102 may be electrically connected to a probing area 110 and a bonding area 111 of the pad afterwards, respectively. The wiring layer 102 may be formed to have a thickness in the range of 5500 to 6500 Å.

A passivation layer 103 is located so as to overlap with a predetermined region at both sides on the wiring layer 102.

Particularly, a protrusion pattern 104 is formed in the passivation layer 103 according to this embodiment of the invention so as to physically divide the first region 110 and the second region 111 corresponding to the first pad contact region 102a and the second pad contact region 102b, afterwards. The passivation layer 103 may be formed of a single film such as a nitride film or an oxide film, or multi films thereof. For example, the passivation layer may be multiple films of a TEOS and a nitride film. The passivation layer 103 may be formed to have a thickness in the range of 500 to 1000 Å, for example.

A barrier metal pattern 107 and a pad metal pattern 108 are formed conformally on the upper side of the passivation layer 103, the exposed wiring layer 102, and the protrusion pattern 104. Here, the pad metal pattern 108 may be formed of any one selected from a group consisting of Al, Al alloy, TaN/Al, and TiN/Al, to have a thickness of about 1000 Å, for example.

According to this embodiment of the invention, the pad metal pattern 108 is divided into the first region 110 corresponding to the first pad contact region 102a and the second region 111 corresponding to the second pad contact region 102b by the protrusion region 109. The first region 110 is a probing area, which can be tested by the probe tip. The second region 111 is a bonding area, which can be wire-bonded. Since the first region 110 and the second region 111 can be physically divided by the protrusion region 109, damage to the surface is restricted within the first region 110 even when the probe tip is pushed during a probing test.

That is, even though the probe tip is brought in contact several times with the first region 110 according to the embodiment of the invention thus causing damage to the surface, the protrusion region 109 physically divides the first region 110 and the second region 111 to prevent the surface of the second region 111 from being damaged by the probing test; therefore, it is possible to prevent defects due to bonding contact during a bonding process afterwards. Accordingly, it is possible to improve yield of a packaging process.

Hereinafter, a method of fabricating a semiconductor device according to an embodiment of the invention will be described with reference to accompanying drawings.

FIGS. 3 to 5 are cross-sectional views subsequently illustrating the processes of fabricating the pad according to an embodiment of the invention.

Referring to FIG. 3, the wiring layer 102 and the passivation layer 103 are formed on the semiconductor substrate 100.

First, the interlayer insulating film 101 is formed on the semiconductor substrate 100.

The interlayer insulating film 101 maybe formed of, for example, a silicon oxide film (SiOx), a silicon oxynitride film (SiON), a titanium oxide film (TiOx), a tantalium oxide film (TaOx), or the like. The wiring layer 102 is formed of copper in the interlayer insulating film 101 by using a damascene process. A copper wiring layer 102 is exemplary, and the wiring layer is not limited thereto. The wiring layer 102 may be formed to have a thickness in the range of 5500 to 6500 Å, for example. Here, the wiring layer 102 is the uppermost wiring layer.

Afterwards, the wiring layer 102 and the interlayer insulating film 101 are planarized by using a CMP (Chemical Mechanical Planarization) or an etch-back process, and the passivation layer 103 is formed on the entire surfaces thereof.

The passivation layer 103 may be formed of a single film such as a nitride film or an oxide film, or multiple films thereof. For example, the passivation layer may be formed of multiple films of a TEOS (Tetra Ethyl Ortho Silicate) and a nitride film. The passivation layer 103 may be formed to have a thickness in the range of 500 to 1000 Å.

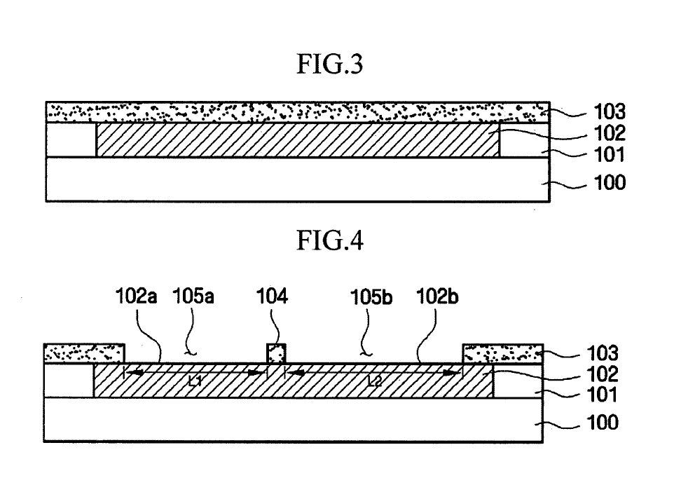

Referring to FIG. 4, a protrusion pattern 104 is formed by etching a predetermined amount of the passivation layer 103.

The passivation layer 103 is etched to expose the first pad contact region 102a and the second pad contact region 102b on the wiring layer 102. Accordingly, it is possible to form a first opening 105a through which the first pad contact region 102a is exposed and a second opening 105b through which the second pad contact region 102b is exposed. Simultaneously, as there is a predetermined region that is not etched while etching the passivation layer 103, the protrusion pattern 104 is formed to divide the first opening 105a and the second opening 105b. Particularly, the passivation layer 103 is etched such that an exposed region L1 of the first opening 105a is smaller than an exposed region L2 of the second opening 105b. By this, as the region of the second opening 105b corresponding to the bonding area is made larger than the region of the first opening 105a corresponding to the probing area in a subsequent process, the bonding process can be stably performed.

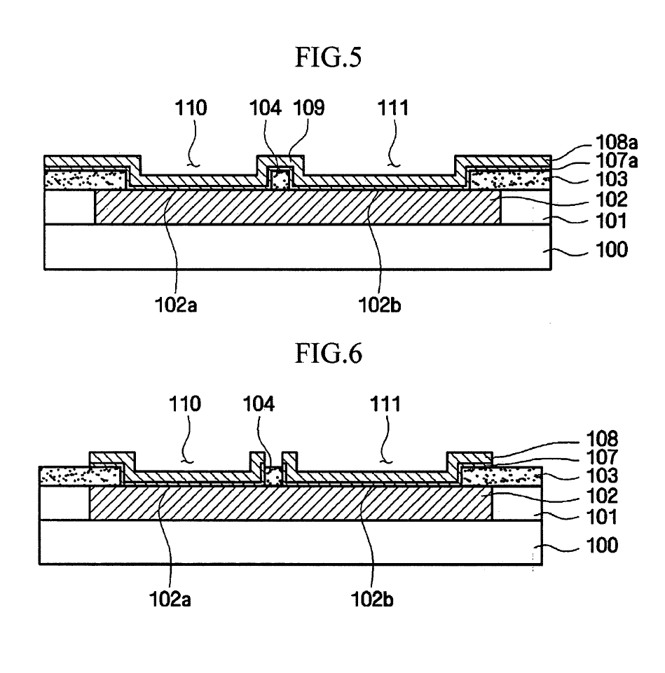

Continuing with reference to FIG. 5, a barrier metal layer 107a and a pad metal layer 108a are formed.

The barrier metal layer 107a is conformally formed along the structure resulting from the above process. The barrier metal layer 107a can prevent copper of the wiring layer 102 from diffusing during the process. The barrier metal layer 107a may be formed of a single film selected from a group consisting of nickel (Ni), cobalt (Co), chrome (Cr), molybdenum (Mo), titanium (Ti), and tungsten (W), or multiple films thereof.

The pad metal layer 108a is conformally formed along the barrier metal layer 107a. The pad metal layer 108a may be formed of one selected from a group consisting of Al, Al alloy, TaN/Al and TiN/Al by using a deposition process. The pad metal layer 108a may be formed to have a thickness of about 1000 Å, for example.

As such, the first region 110 corresponding to the first pad contact region 102a and the second pad contact region 102b corresponding to the second region 111 may be formed. The first region 110 and the second region 111 are divided by the protrusion region 109. The first region 110 is the probing area that can be tested by the probe tip, and the second region 111 is the bonding area on which the bonding process is performed. The protrusion region 109 which is conformally formed at the upper side of the protrusion pattern 104 physically divides the first region 110 and the second region 111, thus dividing the probing area and the bonding area. In addition, even when the probe tip is pushed, the probe tip is prevented from escaping from the first region 110 that is the probing area and damaging the surface of the second region 111. As such, although the probe test may be performed several times, it is possible to prevent damage to the surface of the second region 111 that is the bonding area, thereby preventing defects of bonding due to unstable contact.

In addition, as the first region 110 and the second region 111 correspond to the first pad contact region 102a and the second pad contact region 102b, respectively, wherein the second region 111 has a larger area than the first region 110. Therefore, it is possible to stably perform a bonding process on the second region 111 in a subsequent bonding process.

Returning to FIG. 2B, the pad metal layer and the barrier metal layer are patterned to form the pad metal pattern 108 and the barrier metal pattern 107.

As a predetermined region of the pad metal layer (refer to 108a of FIG. 5) and the barrier metal layer (refer to 107a of FIG. 5) is etched and patterned, the pad metal pattern 108 and the barrier metal pattern 107 can be formed to be aligned with the wiring layer 102. According to the process, the pad metal layer (refer to 108a of FIG. 5) is patterned so as to overlap with a predetermined region at the upper side of the passivation layer 103.

As such, the semiconductor device in which the first region 110 and the second region 111 are physically divided can be obtained by the protrusion pattern 104 and the protrusion region 109.

FIG. 6 is a cross-sectional view illustrating a pad according to another embodiment of the invention.

Hereinafter, in describing this embodiment, repeated description will be omitted and only the difference from that of FIG. 2B will be described in detail.

The pad metal pattern 108 according to this embodiment is formed by completely separating the first region 110 and the second region 111. To be more specific, the pad metal layer (refer to 108a of FIG. 5) and the barrier metal layer (refer to 107a of FIG. 5) are patterned so as to be aligned with both sidewalls of the protrusion pattern 104. As such, the pad metal pattern 108 of the first region 110 and the pad metal pattern 108 of the second region 111 can be completely separated. Then, since the first region 110 and the second region 111 can be physically separated by the protrusion pattern 104, the probing area and the bonding area can be divided in this embodiment as well as in other embodiments of the invention.

In addition, although the pad metal pattern 108 according to the second embodiment of the invention is patterned so as to be aligned with both sidewalls of the protrusion pattern 104, the pad metal pattern can overlap with a predetermined region at the upper side of the protrusion pattern 104 according to the process. The pad metal pattern 108 can be patterned in any manner as long as the first region 110 and the second region 111 are physically and completely separated.

As described above, according to exemplary embodiments of the invention, as the first region 110 and the second region 111 are divided by the protrusion pattern 104 or the protrusion region 109, it is possible to obtain the semiconductor device in which the pad area is physically divided into the probing area and the bonding area. Therefore, when the probe test is repeatedly performed on the first region 110 that is the probing area to evaluate the characteristics of the products, the surface of the pad metal pattern 108 may be scratched by the probe tip thus being damaged in the first region 110, but the surface of the pad metal pattern 108 is not damaged in the second region 111. In addition, even when the probe tip is pushed by external pressure or force, it is possible to prevent the probe tip from being pushed into the second region 111 by forming walls to the bonding area by the protrusion pattern 104 or the protrusion region 109. Therefore, it is possible to prevent yield of the manufacturing process from deteriorating due to defective contact during the bonding process by preventing damage to the surface of the pad metal pattern 108 of the second region 111 that is the bonding area. Further, it is possible to ensure a stable contact region for a ball or wire during the bonding process by forming the second region 111 to have a larger size than the first region 110.

Although embodiments of the present invention has been described in connection with exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

As described above, the semiconductor device of the invention and the method of fabricating the same include the following features.

First, the probing area and the bonding area can be physically divided by the protrusion pattern.

Second, as the probing area is physically separated from the bonding area, even though the probe tip may be brought in contact repeatedly with the probing area, the bonding area is prevented from being damaged by the probe tip.

Third, it is possible to prevent defects from being generated during the bonding process by preventing damage to the surface of the bonding area.

Fourth, it is possible to improve yield of the packaging process by preventing defects from being generated during the bonding process.

What is claimed is:

1. A semiconductor device comprising:
a wiring layer formed on a substrate and comprising a first pad contact region and a second pad contact region;
a passivation layer comprising a first opening and a second opening on the wiring layer and a protrusion pattern dividing the first opening and the second opening, the first pad contact region being exposed through the first opening and the second pad contact region being exposed through the second opening; and
a pad metal pattern conformally formed along the first opening, the second opening, and the protrusion pattern of the passivation layer.

2. The semiconductor device of claim 1, wherein the pad metal pattern comprises a first region corresponding to the first pad contact region and a second region corresponding to the second pad contact region.

3. The semiconductor device of claim 2, wherein the first region is a probing area.

4. The semiconductor device of claim 2, wherein the second region is a bonding area.

5. The semiconductor device of claim 2, wherein the second region is larger than the first region.

6. The semiconductor device of claim 2, wherein the pad metal pattern is divided into the first region and the second region.

7. The semiconductor device of claim 1, wherein the wiring layer is an uppermost wiring layer.

8. The semiconductor device of claim 1, wherein a barrier metal pattern is interposed between the pad metal pattern and the openings.

9. A method of fabricating a semiconductor device, the method comprising:
forming a wiring layer that comprises a first pad contact region and a second pad contact region on a substrate;
forming a passivation layer on the wiring layer;
forming a protrusion pattern, which divides a first opening through which the first pad contact region is exposed and a second opening through which the second pad contact region is exposed, by etching the passivation layer; and
forming a pad metal pattern by patterning a pad metal layer along the first opening, the second opening, and the protrusion pattern of the passivation layer.

10. The method of claim 9, wherein the pad metal pattern comprises a first region corresponding to the first pad contact region and a second region corresponding to the second pad contact region.

11. The method of claim 10, wherein the first region is a probing area.

12. The method of claim 10, wherein the second region is a bonding area.

13. The method of claim 10, wherein the second region is larger than the first region.

14. The method of claim 10, wherein the pad metal pattern is divided into the first region and the second region.

15. The method of claim 9, wherein the wiring layer is an uppermost wiring layer.

16. The method of claim 9, wherein the patterning of the pad metal layer comprises:
patterning the pad metal layer by conformally forming the pad metal layer along the first opening, the second opening, and the protrusion pattern, and
etching the pad metal layer so as to be aligned with the wiring layer.

17. The method of claim 9, further comprising:
forming a barrier metal layer between the pad metal layer and the openings.

18. A semiconductor device comprising:
a wiring layer formed on a substrate and comprising a first pad contact region and a second pad contact region;
a passivation layer comprising a first opening and a second opening on the wiring layer and a protrusion pattern dividing the first opening and the second opening; and
a pad metal pattern conformally formed along the first opening, the second opening, and the protrusion pattern of the passivation layer, the pad metal pattern comprising a first region corresponding to the first pad contact region and a second region corresponding to the second pad contact region.

19. The semiconductor device of claim 18, wherein the first pad contact region is exposed through the first opening and the second pad contact region is exposed through the second opening.
